(19) United States
(12) Patent Application Publication
(10) Pub. No.: US 2021/0262088 A1
(43) Pub. Date: Aug. 26, 2021

(54) METHOD FOR IMPROVED PROCESSING WITH NEUTRAL RADICALS AND OTHER MEAN FREE PATH LIMITED SPECIES

(71) Applicant: Laminera LLC, Berkeley, CA (US)

(72) Inventor: Lauren M. Otto, Berkeley, CA (US)

(21) Appl. No.: 17/174,150

(22) Filed: Feb. 11, 2021

Related U.S. Application Data
(60) Provisional application No. 62/975,120, filed on Feb. 11, 2020.

(51) Int. Cl. C23C 16/455

(52) U.S. Cl. CPC C23C 16/45527; C23C 16/45553

(57) ABSTRACT

This invention relates to substrate processing and describes a method for depositing a film on a substrate in a substrate processing chamber, the substrate comprising a surface comprising a surface species, the method comprising: depositing a layer of material on the substrate surface by flowing a precursor into the chamber and over the substrate surface to form a material layer on the substrate surface, the material layer comprising ligands remaining from the precursor; substantially removing excess molecular precursor from the processing chamber; flowing one or more reactive species into the substrate processing chamber and over the surface of the substrate to remove the ligands and combine with the material surface forming a compound with the material, the reactive species comprising one or more mean free path limited species with at least one inert gas species being flowed into the substrate processing chamber simultaneously with the mean free path limited species.

### CROSS-REFERENCE TO RELATED APPLICATIONS

This application claims the benefit of U.S. Provisional Application No. 62/975,120, filed on 11 Feb. 2020, and entitled “Method for improved processing with neutral atomic species and other radicals,” the entire contents of which are incorporated by reference herein.

### STATEMENT OF GOVERNMENT SUPPORT

This invention was made with government support under a CRADA (FP00005818) between (Laminera LLC) and Lawrence Berkeley National Laboratory.

The government has certain rights in this invention.

### BACKGROUND

Atomic layer deposition is a chemical vapor-based deposition technique wherein reactive gases or vapors interact with a substrate surface in a substrate processing chamber in order to deposit a film on the surface of the substrate. Traditional chemical vapor deposition combines the reactants concurrently in the substrate processing chamber, incorporates heat to assist the chemical reactions required for film deposition, and can be done at varying pressures and with or without plasma assistance. The use of vapor or gases allows for isotropic or conformal deposition as the vapors or gases can reach surfaces outside of the line of sight of the vapor or gas source. Depending on substrate surface features and their aspect ratios as well as the process of deposition can impact the degree to which the isotropic or conformal nature of the deposited film is achieved. Atomic layer deposition was originally developed as a sequential form of chemical vapor deposition wherein at least some of the reactants which form the film are no longer in the same substrate processing chamber at the same time. Their segregation allows for the precise control of the formation of the film, which traditionally happens layer by layer in a self-limiting process where a reactant is allowed to saturate the surface with a single layer of itself, the excess is removed via pumping and/or purging with an inert gas, and then an alternate reactant is introduced and allowed to saturate the surface with a single layer of itself and there to react with the earlier reactant(s), the excess is removed via pumping and/or purging with an inert gas, and so on, which can be repeated until the desired film thickness is reached. As such, atomic layer deposition found its niche in applications where films needed to be thin and uniform over large areas and abstract shapes, in particular those with high aspect ratios (e.g. deep holes or trenches but with narrow openings). Traditional atomic layer deposition boasts near perfect conformality for aspect ratios in excess of 10,000:1. Suitable atomic layer deposition reactive molecular precursors include but are not limited to halogen-based precursors such as TiCl₄, TaBr₅, H₂SiCl₂, and PbI₂, for example, organometallic precursors such as TDMAT (tetrakisdimethylamido titanium), copper(II) hexafluoroacetylacetonate, and TTIP (titanium tetraisopropoxide), for example, as well as many other precursors and other types of precursors. Other suitable reactants for traditional atomic layer deposition include but are not limited to NH₃, H₂O, and O₃, for example. Common surface species found in atomic layer deposition include but are not limited to OH groups or hydroxyls, H-terminated surfaces, surfaces terminated with N, O, C, S, Se, P, F, Br, Cl, I, Ti, Al, Si, Ta, Zr, Co, Au, Ag, Pt, or various other elements. Atomic layer deposition comprises a wide scope of materials.

To make possible new chemistries and lower deposition temperatures for use in new applications, radical assisted sequential chemical vapor deposition (also known as plasma enhanced atomic layer deposition) was developed and replaced a portion of previous reactants with the species present in or from a plasma including radicals, which are defined as unstable species (for example, radical forms of oxygen include but are not limited to ionized O₂ and neutral and/or ionized O and O₃, for example). Plasmas can be generated in many ways including direct plasmas, capacitively coupled plasmas, inductively coupled plasmas, hollow cathode plasmas, electron cyclotron resonance plasmas, etc. In the case of a direct plasma, the substrate is positioned within the plasma itself or the plasma's sheath and is subjected to all of the plasma's species including ionized and neutral radicals, electrons, and photons. In contrast, in the case of an inductively coupled plasma, the substrate is traditionally positioned outside of the plasma and is only subjected to the species that make it out of the plasma or the plasma's sheath and are able to reach the substrate. In any of these configurations, ions may form a substantial, dominant, or at minimum a present and impactful component of the film growth and quality. While ions can be used to improve the quality of some films, including hard and conductive films like TiN, other films such as dielectrics and structures with electrical functions can be more vulnerable to ions via the sputtering of the film or substrate or an induced current due to excess ions. Similar electrical vulnerability can also exist with the electrons and photons present in the plasma. This sputtering and electrical damage to the film and/or substrate is known as “RF damage.”

With the motivation to mitigate the “RF damage” but still retain the advantages of plasma enhanced atomic layer deposition, it can be desirable to ensure that the substantial portion of species allowed to interact with the substrate are the neutral radical species since they are not electrically charged and therefore will not contribute to the formation of undesired currents or charge accumulation, and their lack of electrical charge makes them a more gentle (i.e. less likely to sputter etch the film or substrate) reactant relative to the more aggressive ions.

This invention relates generally to the field of substrate processing techniques, more specifically atomic layer deposition, and most specifically to a new and useful method for improving atomic layer deposition with mean free path limited species, such as but not limited to neutral atomic species, other neutral radicals including neutral molecular radicals, or electrons.

### BRIEF DESCRIPTION OF THE FIGURES

FIG. 1 is a set of black and white image representations of annotated transmission electron microscopy images demonstrating the effectiveness of an example embodiment of what is claimed.

FIG. 2 is a method figure or flowchart depicting the method invention herein.

FIG. 3 is a drawing of an example system in which an embodiment of the method invention could be performed.

### DESCRIPTION OF THE EMBODIMENTS

The following description of the embodiments of the invention is not intended to limit the invention to these embodiments but rather to enable a person skilled in the art to make and use this invention.

With the motivation to mitigate the “RF damage” but still retain the advantages of plasma enhanced atomic layer deposition, it can be desirable to ensure that the substantial portion of species allowed to interact with the substrate are the neutral radical species since they are not electrically charged and therefore will not contribute to the formation of undesired currents or charge accumulation, and their lack of electrical charge makes them a more gentle (i.e. less likely to sputter etch the film or substrate) reactant relative to the more aggressive ions.

This invention relates generally to the field of substrate processing techniques, more specifically atomic layer deposition, and most specifically to a new and useful method for improving atomic layer deposition with mean free path limited species, such as but not limited to neutral atomic species, other neutral radicals including neutral molecular radicals, or electrons.

Provided herein is a method for improving atomic layer deposition with radical species, and specifically mean free path limited species such as neutral atomic species, neutral molecular radical species, and electrons, to name a few. The method provided herein functions to improve the conformality of films generated with such methods, especially when the method of delivery for the mean free path limited species involves a directional nature of motion for said species.

Neutral radical species can be generated directly and delivered to the substrate, or they can be obtained in another way, such as via the use of a ceramic or metal aperture plate or screen at or around the edge of the plasma or its sheath or around the boundary between the plasma and the substrate processing chamber in order to neutralize the ionized species that pass through the aperture plate or screen via a charge exchange. This process of generating, neutralizing, isolating, etc. the neutral radical species naturally introduces considerable directionality to these reactive species relative to the reactive vapor or gas species used in traditional atomic layer deposition, which will lead to challenges in achieving conformality in even moderate aspect ratio structures. Traditional plasma enhanced atomic layer deposition also experiences a similar but seemingly less significant reduction in conformality in high aspect ratio structures due to the plasma sheath's electric field orienting the ions, but uniform thicknesses have been routinely achieved for aspect ratios in excess of 30:1.

The neutral radical species are mean free path limited in nature due to their high likelihood to combine or recombine with other species or each other upon a close encounter. Ions do not have this limitation as their like charge will cause them to repel upon a close approach, and additional electrons would be needed to form a stable species. The present application is directed to processing approaches, both systems and methods, designed specifically for the mean free path limitation unique to neutral radical species (and electrons).

Mean free path is dependent on the partial pressure of the mean free path limited species, their kinetic energy, and the species' size. As discussed above, the mean free path limited species' kinetic energy is considerably directional, which would result in species arriving at roughly normal incidence relative to the substrate surface for a plasma source positioned across from the substrate surface.

Concerning fluid flow in vacuum, we can define a number known as the Knudsen number (Kn), which is the ratio of the mean free path (λ) of a species to the diameter (d) of the flow channel (e.g. the substrate processing chamber), or Kn=λ/d. For small Kn<0.01, the flow is considered viscous flow and may be laminar or turbulent depending on the Reynold's number. For higher Kn>0.5, the flow is considered molecular flow, and the species in the flow channel simply travel in straight lines until encountering another object from which they will bounce off. For moderate 0.01<Kn<0.5, the flow is considered Knudsen flow and is a combination of or a transition between viscous flow and molecular flow. Some sources consider 0.5<Kn<10 to be a combination or a transition between viscous flow and molecular flow as well. If an inert gas species is introduced into the substrate processing chamber, that inert gas species will gain kinetic energy in a variety of directions as it experiences molecular flow within the substrate processing chamber. If the inert gas species is introduced into the substrate processing chamber while the considerably directional mean free path limited species is also present in the substrate processing chamber, the inert gas species will essentially provide sources of changing the directionality of the mean free path limited species and enabling them to better reach the sidewalls of vertical structures or other spaces on the substrate surface that are shadowed by the substrate's features or outside the line of sight of the mean free path limited species' source. Embodiments of the method invention herein prefer to operate in the moderate to high Kn regimes where molecular flow is present so as to improve conformality and resolve conformality issues previously inherent in substrate processing approaches that mitigate RF damage problems and incorporate mean free path limited species.

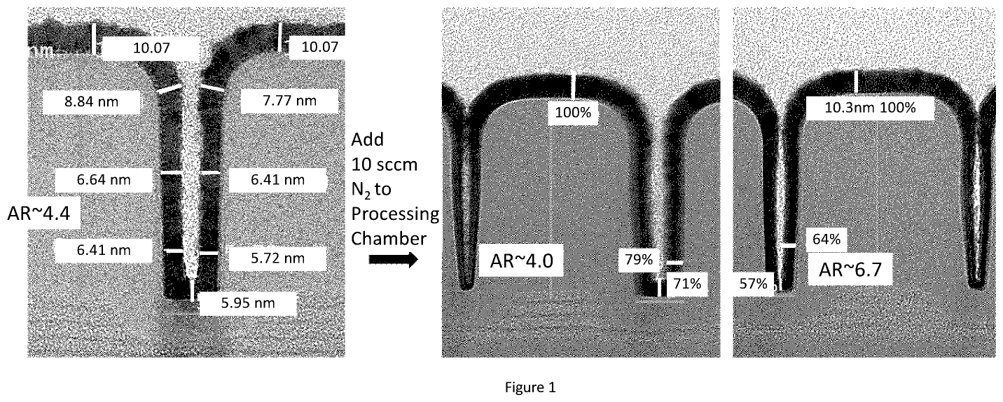

FIG. 1 shows results from preferred and demonstrated embodiment where the inert species N₂ being delivered at a flow rate of 10 sccm through a different port than the mean free path limited species, the combination of species bringing the pressure of the substrate processing chamber up to around the Knudsen flow or molecular flow regimes. The substrate comprising silica ridges with varying aspect ratio gaps in between, where the aspect ratio (AR) is defined by the ratio of the height (h) of the gap to the width (w) of the gap, or AR=h/w. The deposited film using the method invention described herein comprising TiN formed from the molecular precursor TiCl₄ and the mean free path limited species neutral atomic nitrogen and neutral atomic hydrogen with generated reaction byproduct comprising HCl. The conformality being defined as a percentage of the film thickness on the top of the ridge. The transmission electron microscopy image on the left shows the resulting film when no inert gas species is used during the processing step or steps containing mean free path limited species. The conformality at the bottom of a 4.4 AR gap is 59%, a far cry from the usually 100% conformality that traditional atomic layer deposition offers. Upon introducing an inert gas species into the substrate processing chamber during the processing step or steps containing mean free path limited species, the conformality improves and achieves a similar value (57%) for a larger aspect ratio (6.7) and a higher value (71% conformality) for a similar (but slightly smaller) aspect ratio (4.0). Furthermore, the TiN film deposited using the method disclosed herein also appears darker in the transmission electron microscopy images on the right implying that the film is more electron dense, which means that the film has a higher carrier concentration and would be of higher quality. Finally, the 10 sccm flow rate of N₂ is only an example flow rate that could be used in the method herein. The flow rate needed and pressure achieved trades off with the substrate processing chamber size and pumping speed, which can be controlled using a throttle valve whose position can be changed across a spectrum of open to closed in order to balance the available flow with the desired pressure (and flow regime) in the substrate processing chamber of a given size. In this example, the partial pressure of the mean free path limited species and the inert species were each around 10-4 to 1-3 Torr, and the total flow rate of gas into the substrate processing chamber and the inductively coupled plasma source region were around 20-30 sccm. The substrate processing chamber was around 1-10 L, and the maximum pumping speed was around 200-300 L/s. The concept shown herein is not intended to limit the scope of the method invention disclosed herein but instead is an example of demonstrated embodiment that is a subset of all possible embodiments of this method invention. The concept shown herein can be further optimized to further improve the conformality of films deposited with mean free path limited species.

Herein the term “reactive species” can refer to reactive molecular precursors such as halogen-based and organometallic precursors, for example, other traditional reactive species used in atomic layer deposition such as NH₃, H₂O, and O₃, for example, any radical species generated by a plasma including ions, electrons, neutral radicals molecular or atomic, and photons, for example, mean free path species generated using another method such as electrons, for example, and photons, which can be used to trigger chemical reactions or responses.

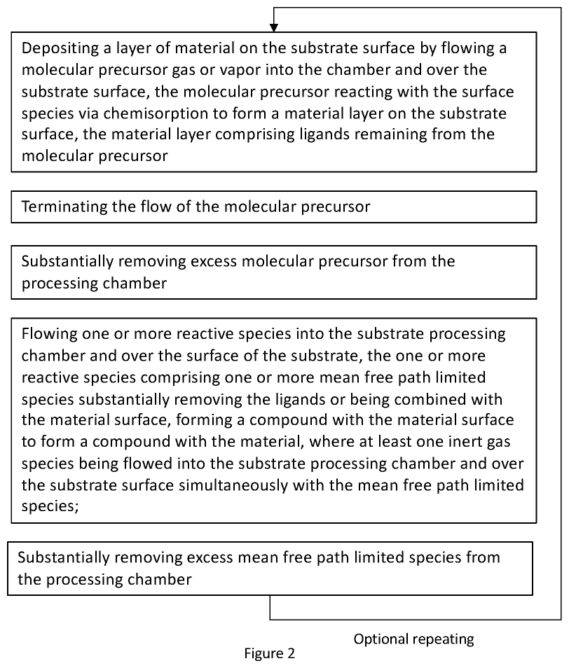

FIG. 2 shows a method for depositing a film on a substrate in a substrate processing chamber, the substrate comprising a surface comprising a surface species, the method comprising:
a. Depositing a layer of material on the substrate surface by flowing a molecular precursor gas or vapor into the chamber and over the substrate surface, the molecular precursor reacting with the surface species via chemisorption to form a material layer on the substrate surface, the material layer comprising ligands remaining from the molecular precursor;
b. Terminating the flow of the molecular precursor;
c. Substantially removing excess molecular precursor from the processing chamber;
d. flowing one or more reactive species into the substrate processing chamber and over the surface of the substrate, the one or more reactive species comprising one or more mean free path limited species substantially removing the ligands or being combined with the material surface, forming a compound with the material surface to form a compound with the material, where at least one inert gas species being flowed into the substrate processing chamber and over the substrate surface simultaneously with the mean free path limited species;
e. Substantially removing excess mean free path limited species from the processing chamber;
f. Optionally repeating the steps a) through e) any number of times to form the film.

A variation of the method such as method m100 where the mean free path limited species comprises one or more of: electrons, neutral atomic hydrogen, neutral atomic nitrogen, neutral atomic oxygen, neutral atomic carbon, neutral atomic sulfur, neutral atomic selenium, neutral atomic fluorine, neutral atomic phosphorus, or another neutral atomic species.

A variation of the method such as method m100 where the mean free path limited species comprises a neutral molecular radical containing N, H, C, O, S, Se, F, or P, for example.

A variation of the method such as method m100 where the inert gas species is He, Ne, Ar, Kr, Xe, N₂, or another noble or inert gas species.

A variation of the method such as method m100 where the ligand removed is hydrogen or contains a halogen, contains carbon, or contains oxygen.

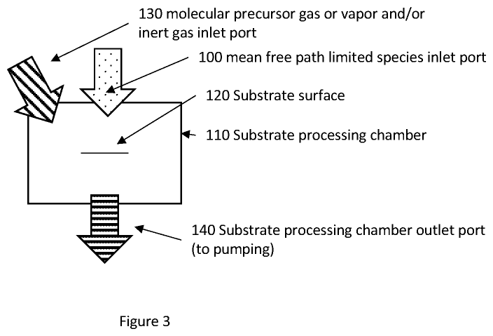

As shown in FIG. 3, a variation of the method such as method m100 where the inert gas species in step d is flowed into the substrate processing chamber 110 from a different input port 130 than a mean free path limited species (port 100 in example shown in FIG. 3), or alternatively, where the inert gas species in step d is flowed into the substrate processing chamber from the same input port as a the mean free path limited species. The inert gas species and the mean free path limited species flowing over the substrate surface 120. The substrate processing chamber 110 also includes an outlet port, which is used for pumping the substrate processing chamber.

A variation of the method such as method m100 where the partial and/or total pressures of the species (inert species and mean free path limited species) present in the substrate processing chamber in step d are around or in the Knudsen flow regime and/or molecular flow regime.

A variation of the method such as method m100 where the mean free path limited species flow from at least one input port in the substrate processing chamber that is positioned roughly within one mean free path length from the substrate.

A variation of the method such as method m100 where the mean free path limited species flow from at least one input port in the substrate processing chamber that is positioned roughly normal to the substrate surface, or more generally, where the mean free path limited species flow from at least one input port in the substrate processing chamber that contains the substrate surface in its line of sight.

A variation of the method such as method m100 where the species being reactive with the ligands on the material surface in order to substantially remove the ligands and the mean free path limited species are isolated in separate steps or paired in a variety of ways in more than one step.

A variation of the method such as method m100 where the mean free path limited species are isolated in separate steps or paired in a variety of ways in more than one step.

A method for depositing a film on a substrate in a chamber where at least one inert gas species is added to a substrate processing chamber during a processing step that involves at least one mean free path limited species.

A variation of the method such as method m200 where any inert gas species added to a substrate processing chamber improves the conformality of the film.

A method for depositing a film on a substrate in a chamber where at least one inert gas species is added to a substrate processing chamber during a processing step that involves at least one mean free path limited species where the inert gas species added to a substrate processing chamber improves the conformality of the film.

Films made using the above-described methods also are provided herein.

The methods may be used with or otherwise make use of systems and methods described in the following references, the entire contents of each of the following references are incorporated by reference herein: KR10-2005-0023782, U.S. Pat. Nos. 8,187,679, 8,637,123B2, 6,605,549B2, 6,638,862, 4,389,973, 5,916,365, 6,200,893, 6,388,383, 6,616,986, 7,798,096, 7,919,142, US20040060657A1, US20110159204A1, US20140272179A1, US20150053259A1, and US20160013020A1.

As a person skilled in the art will recognize from the previous detailed description and from the figures and claims, modifications and changes can be made to the embodiments of the invention without departing from the scope of this invention as defined in the following claims.

What is claimed is:

1. A method for depositing a film on a substrate in a substrate processing chamber, the substrate comprising a surface comprising a surface species, the method comprising:
a) depositing a layer of material on the substrate surface by flowing a molecular precursor gas or vapor into the chamber and over the substrate surface, the molecular precursor reacting with the surface species via chemisorption to form a material layer on the substrate surface, the material layer comprising ligands remaining from the molecular precursor;
b) terminating the flow of the molecular precursor;
c) substantially removing excess molecular precursor from the processing chamber;
d) flowing one or more reactive species into the substrate processing chamber and over the surface of the substrate, the one or more reactive species comprising one or more mean free path limited species substantially removing the ligands or being combined with the material surface, forming a compound with the material surface to form a compound with the material, where at least one inert gas species being flowed into the substrate processing chamber and over the substrate surface simultaneously with the mean free path limited species;
e) substantially removing excess mean free path limited species from the processing chamber; and
f) optionally repeating the steps a) through e) any number of times to form the film.

2. The method of claim 1 where the mean free path limited species comprises one or more of: electrons, neutral atomic hydrogen, neutral atomic nitrogen, neutral atomic oxygen, neutral atomic carbon, neutral atomic sulfur, neutral atomic selenium, neutral atomic fluorine, neutral atomic phosphorus, or another neutral atomic species.

3. The method of claim 1 where the mean free path limited species comprises a neutral molecular radical containing N, H, C, O, S, Se, F, or P.

4. The method of claim 1 where the inert gas species is He, Ne, Ar, Kr, Xe, N₂, or another noble or inert gas species.

5. The method of claim 1 where the ligand removed is hydrogen or contains a halogen, contains carbon, or contains oxygen.

6. The method of claim 1 where the inert gas species in step d is flowed into the substrate processing chamber from a different input port than a mean free path limited species, or alternatively, where the inert gas species in step d is flowed into the substrate processing chamber from the same input port as a the mean free path limited species.

7. The method of claim 1 where the partial and/or total pressures of the species (inert species and mean free path limited species) present in the substrate processing chamber in step d are around or in the Knudsen and/or molecular flow regimes and the transition region between the two.

8. The method of claim 1 where the mean free path limited species flow from at least one input port in the substrate processing chamber that is positioned roughly within one mean free path length from the substrate.

9. The method of claim 1 where the mean free path limited species flow from at least one input port in the substrate processing chamber that is positioned roughly normal to the substrate surface, or more generally, where the mean free path limited species flow from at least one input port in the substrate processing chamber that contains the substrate surface in its line of sight.

10. The method of claim 1 where the species being reactive with the ligands on the material surface in order to substantially remove the ligands and the mean free path limited species are isolated in separate steps or paired in a variety of ways in more than one step.

11. The method of claim 1 where the mean free path limited species are isolated in separate steps or paired in a variety of ways in more than one step.

12. A method for depositing a film on a substrate in a chamber where at least one inert gas species is added to a substrate processing chamber during a processing step that involves at least one mean free path limited species.

13. The method of claim 12 where any inert gas species added to a substrate processing chamber improves the conformality of the film.

14. A method for depositing a film on a substrate in a chamber where at least one inert gas species is added to a substrate processing chamber during a processing step that involves at least one mean free path limited species where the inert gas species added to a substrate processing chamber improves the conformality of the film.

15. A film made using the method of claim 1.

16. A film made using the method of claim 12.

17. A film made using the method of claim 14.
